(19) United States
(12) Patent Application Publication
(10) Pub. No.: US 2026/0026317 A1
(43) Pub. Date: Jan. 22, 2026

(54) METHOD FOR MANUFACTURING SEMICONDUCTOR DEVICE

(71) Applicant: Resonac Corporation, Minato-ku, Tokyo (JP)

(72) Inventors: Yuki MIYAMOTO, Minato-ku, Tokyo (JP); Chikash AOYAGI, Minato-ku, Tokyo (JP); Yoshikatsu TOUBARU, Minato-ku, Tokyo (JP); Masayuki WADA, Minato-ku, Tokyo (JP); Kelichi SAKAMOTO, Minato-ku, Tokyo (JP); Shigeru YAMAKI, Minato-ku, Tokyo (JP); Tatsuya MAKINO, Minato-ku, Tokyo (JP); Hidekazu KONDO, Minato-ku, Tokyo (JP)

(21) Appl. No.: 18/860,824

(22) PCT Filed: Mar. 28, 2024
(86) PCT No.: PCT/JP2024/012843

§ 371 Date: Oct. 28, 2024

(30) Foreign Application Priority Data
Mar. 31, 2023 (JP) 2023-058043

(51) Int. Cl. H01L 21/027; H01L 21/78

(52) U.S. Cl. CPC H01L 21/0275; H01L 21/78

(57) ABSTRACT

A method for manufacturing a semiconductor device is disclosed. The method for manufacturing a semiconductor device includes forming a positive photosensitive resin film on a surface of a semiconductor wafer; exposing a part of the positive photosensitive resin film to light and providing an exposed portion on the positive photosensitive resin film; developing the positive photosensitive resin film using a developer and removing the exposed portion to form a pattern; obtaining a patterned semiconductor chip by performing plasma dicing using the pattern as a mask and singulating the semiconductor wafer; exposing a pattern of the patterned semiconductor chip; and obtaining a semiconductor chip in which the pattern is removed from the patterned semiconductor chip by removing the pattern exposed by using a removing liquid.

### TECHNICAL FIELD

The present disclosure relates to a method for manufacturing a semiconductor device.

### BACKGROUND ART

The semiconductor device is generally manufactured through the following steps. First, a semiconductor wafer is attached to a dicing tape, and in this state, the semiconductor wafer is singulated into semiconductor chips (dicing step). Thereafter, steps such as a pickup step of picking up a semiconductor chip, and a semiconductor chip bonding step of bonding the picked-up semiconductor chip and a support member or the like by bonding via an adhesive (die-bonding film) or the like are performed to manufacture a semiconductor device.

As one of dicing methods in the dicing step, a method for cutting a semiconductor wafer by performing plasma etching (dry etching) along a line to cut of the semiconductor wafer is known. The process of processing a semiconductor wafer by this dicing method is referred to as plasma dicing.

In the plasma dicing, usually, a protective film is formed on a surface of a semiconductor wafer, and a part of the protective film is removed by burning off (laser grooving) by being irradiated with a laser along a line to cut to form a pattern (mask) from the protective film. In the laser grooving, a fine cut product (debris) derived from a protective film, a semiconductor wafer, or the like is generated, and the debris remains on the side surface of the obtained semiconductor chip, so that the qualities of the semiconductor chip may be deteriorated. Patent Literature 1 has studied suppression of remaining of debris in plasma dicing.

### CITATION LIST

### Patent Literature

Patent Literature 1: JP 2019-050237 A

### SUMMARY OF INVENTION

### Technical Problem

An object of the present disclosure is to provide a novel method for manufacturing a semiconductor device including performing plasma dicing.

### Solution to Problem

The present disclosure provides methods for manufacturing a semiconductor device of [1] to [3].
[1] A method for manufacturing a semiconductor device, the method including:
forming a positive photosensitive resin film on a surface of a semiconductor wafer;
exposing a part of the positive photosensitive resin film to light and providing an exposed portion on the positive photosensitive resin film;
developing the positive photosensitive resin film using a developer and removing the exposed portion to form a pattern;
obtaining a patterned semiconductor chip by performing plasma dicing using the pattern as a mask and singulating the semiconductor wafer;
exposing a pattern of the patterned semiconductor chip; and
obtaining a semiconductor chip in which the pattern is removed from the patterned semiconductor chip by removing the pattern exposed by using a removing liquid.
[2] The method for manufacturing a semiconductor device according to [1],
in which the positive photosensitive resin film contains a resin in which the molecular weight is reduced by irradiation with light.
[3] The method for manufacturing a semiconductor device according to [2],
in which the developer and the removing liquid are aqueous solvents having pH of 11 or less.

### Advantageous Effects of Invention

According to the present disclosure, a novel method for manufacturing a semiconductor device including performing plasma dicing is provided. According to the method for manufacturing a semiconductor device of the present disclosure, a pattern (mask) can be formed without performing laser grooving processing, and occurrence of debris itself can be suppressed.

### BRIEF DESCRIPTION OF DRAWINGS

FIG. 1 is a schematic cross-sectional view illustrating an embodiment of a method for manufacturing a semiconductor device, and FIGS. 1(a), 1(b), 1(c), and 1(d) are views illustrating respective steps.

FIG. 2 is a schematic cross-sectional view illustrating an embodiment of a method for manufacturing a semiconductor device, and FIGS. 2(a), 2(b), 2(c), 2(d), and 2(e) are views illustrating respective steps.

### DESCRIPTION OF EMBODIMENTS

Hereinafter, the present embodiment is described in detail with reference to the drawings. However, the present disclosure is not limited to the following embodiments. In the following embodiments, the components (including steps and the like) are not essential unless otherwise specified. The same or corresponding portions are denoted by the same reference numerals, and redundant description will be omitted. Further, unless otherwise specified, the positional relationship such as up, down, left, and right is based on the positional relationship illustrated in the drawings. The sizes of components in the drawings are conceptual, and the relative relationship between the sizes of the components is not limited to that illustrated in the drawings.

The same applies to numerical values and ranges thereof in the present disclosure, and the present disclosure is not limited thereto. In the present specification, a numerical range indicated by using “to” indicates a range including numerical values described before and after “to” as a minimum value and a maximum value, respectively. In the numerical ranges described in stages in the present specification, the upper limit value or the lower limit value described in one numerical range may be replaced with the upper limit value or the lower limit value of the numerical range described in another stage. In addition, in the numerical range described in the present specification, the upper limit value or the lower limit value of the numerical range may be replaced with a value shown in examples.

In the present specification, the term “layer” includes a structure having a shape partially formed in addition to a structure having a shape formed on the entire surface when observed as a plan view. In the present specification, the term “step” includes not only an independent step but also a step that cannot be clearly distinguished from other steps as long as an intended action of the step is achieved.

In the present specification, (meth)acrylate means acrylate or methacrylate corresponding thereto. The same applies to other similar expressions such as a (meth)acrylic copolymer.

The components and materials exemplified in the present specification may be used singly or in combination of two or more kinds thereof unless otherwise specified.

### [Method for Manufacturing Semiconductor Device]

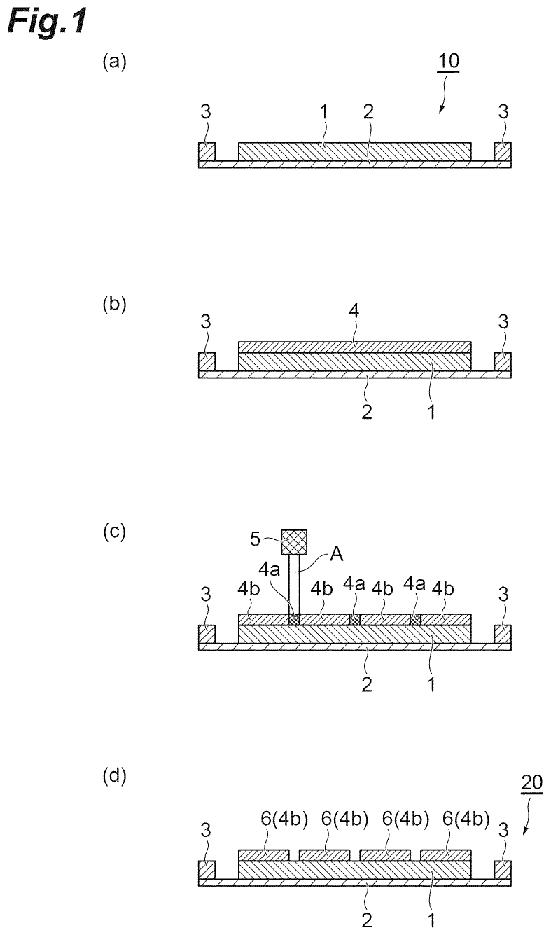

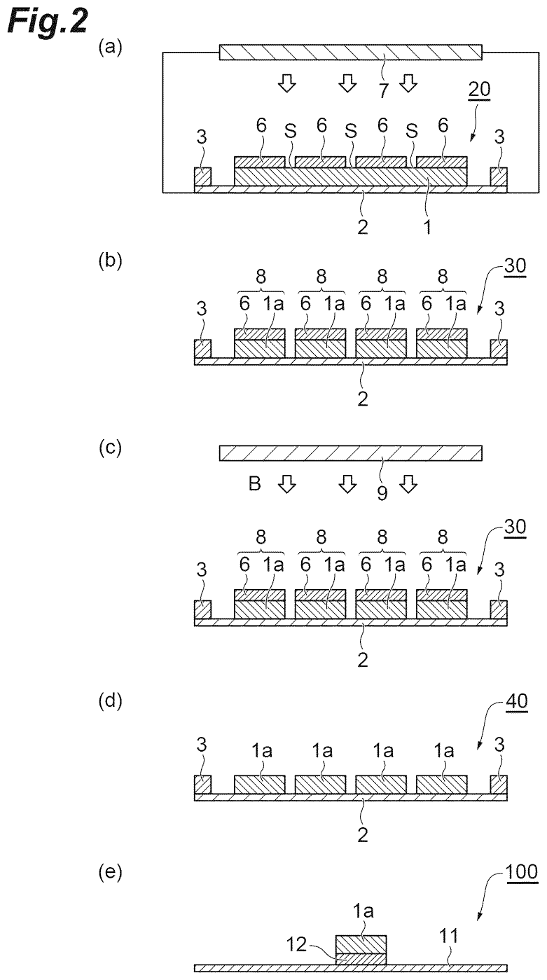

The method for manufacturing a semiconductor device according to the present embodiment includes forming a positive photosensitive resin film on a surface of a semiconductor wafer (hereinafter, referred to as “step (A)”), exposing a part of the positive photosensitive resin film and providing an exposed portion on the positive photosensitive resin film (hereinafter, referred to as “step (B)”), developing the positive photosensitive resin film using a developer and removing the exposed portion to form a pattern (hereinafter, referred to as “step (C)”), obtaining a patterned semiconductor chip by performing plasma dicing using the pattern as a mask and singulating the semiconductor wafer (hereinafter, referred to as “step (D)”), exposing a pattern of the patterned semiconductor chip (hereinafter, referred to as “step (E)”), and obtaining a semiconductor chip in which the pattern is removed from the patterned semiconductor chip by removing the pattern exposed by using a removing liquid (hereinafter, referred to as “step (F)”). FIGS. 1 and 2 are schematic cross-sectional views illustrating an embodiment of the method for manufacturing a semiconductor device.

### <Step (A)>

In this step, a positive photosensitive resin film 4 is formed on the surface of a semiconductor wafer 1.

The positive photosensitive resin film 4 is a resin film in which an exposed portion having increased solubility is removed by a treatment with a developer and an unexposed portion remains. The positive photosensitive resin film 4 may include, for example, a known positive photoresist material.

The positive photosensitive resin film 4 may contain a resin in which the molecular weight is reduced by irradiation with light (hereinafter, the resin may be referred to as a “light meltable resin”). The light meltable resin may be a resin having properties such as deterioration of an elastic modulus and an increase in a loss tangent (tan δ) due to the reduction of the molecular weight by irradiation with light. The light meltable resin is a water-insoluble resin and may be a resin having properties in which the molecular weight is reduced due to the irradiation with light to obtain a water-soluble gel or liquid (solubility in an aqueous solvent is increased).

In one embodiment, the light meltable resin may be a reaction product of a compound A having a disulfide bond and two or more thiol groups and a compound B having two or more functional groups capable of reacting with a thiol group. The positive photosensitive resin film 4 may further contain a photoradical generator in addition to the light meltable resin. The positive photosensitive resin film 4 may further contain a curing accelerator or the like that accelerates the reaction of the compound A and the compound B.

The mechanism by which the light meltable resin is reduced in molecular weight (melted) is not necessarily clear, but for example, the following mechanism is considered. However, the present invention is not limited to these mechanisms. The light meltable resin contains a compound having a disulfide bond (a reaction product of the compound A and the compound B). When the light meltable resin contained in the positive photosensitive resin film 4 is irradiated with light, disulfide bonds in the light meltable resin are decomposed (cleaved) to generate a thiyl radical. At this time, when the photoradical generator (intramolecular cleavage type photoradical generator) is present, the thiyl radical and the photoradical generator react with each other, and the thiyl radical is capped by the photoradical generator. As a result, it is considered that the molecular weight of the compound having a disulfide bond is reduced, and the cured product is light-softened (light-melted). As another mechanism, it is also conceivable that a light-induced radical caused by a photoradical generator (intramolecular cleavage type photoradical generator) directly reacts with a disulfide bond, to form a light-induced radical-thioether bond and generate a thiyl radical, the thiyl radical reacts with another light-induced radical, the molecular weight of the compound having a disulfide bond itself is reduced, and a photocured product is softened. It can be said that the reaction in which the disulfide bond is cleaved is an irreversible reaction.

The positive photosensitive resin film 4 containing a light meltable resin can be formed, for example, by arranging a curable composition containing the compound A, the compound B, and the photoradical generator, and a curing accelerator as necessary on the surface of the semiconductor wafer 1 and curing the curable composition by heating or light irradiation (reacting the compound A and the compound B). At this time, it can be said that the positive photosensitive resin film 4 contains a cured product of the curable composition. It can be said that the cured product of the curable composition contains a reaction product of the compound A and the compound B and a photoradical generator. Here, the curable composition may be a thermosetting composition that is cured by heating or a photocurable composition that is cured by light irradiation and is preferably a thermosetting composition. Hereinafter, each component of the curable composition is described.

### (Compound A)

The compound A is a compound having a disulfide bond (—S—S—) and having two or more thiol groups (—SH). The upper limit of the number of thiol groups in the compound A may be, for example, ten or less, eight or less, six or less, or four or less. A component (A) may be, for example, a dithiol compound which is a compound having two thiol groups (—SH). The component (A) may be a high molecular weight component of a polymer or an oligomer. A compound having two thiol groups (—SH) can be regarded as a compound containing two thiol groups and a group containing a disulfide bond and linking the two thiol groups (first linking group).

The molecular weight or number average molecular weight of the compound A may be, for example, 100 to 10,000,000, 200 to 3,000,000, 300 to 1,000,000, 400 to 10,000, or 500 to 5,000. Note that the number average molecular weight is a value in terms of polystyrene using a calibration curve by standard polystyrene by gel permeation chromatography (GPC).

The compound A has one or more (two or more) disulfide bonds in the molecule. The number of disulfide bonds in the compound A may be, for example, 1 to 1,000 or 4 to 50.

The compound A may be a compound having a linear or branched molecular chain and a terminal group and having a disulfide bond in the molecular chain (for example, polymers or oligomers). In this case, the terminal group in the compound A may be a thiol group. When the curable composition contains such a compound as the compound A, the light meltability of the light meltable resin (a reaction product of the compound A and the compound B) tends to be further improved. The molecular chain in the compound A may contain a disulfide bond and a polyether chain or may consist of a disulfide bond and a polyether chain.

The compound A may be, for example, a compound represented by Formula (1): HS—(X—S—S)ₙ₁—X—SH (the compound (1)). In the formula, X represents a polyether chain. A plurality of Xs may be the same as or different from each other. n1 represents an integer of 1 or more. n1 may be, for example, 1 or more or 4 or more or may be 1,000 or less. When the component (A) is a compound represented by Formula (1), a group represented by —(X—S—S)ₙ₁—X— is a first linking group. The compound obtained by extending the chain of the compound (1) may be, for example, a Michael adduct of the compound (1) or a thiourethanized product of the compound (1).

The polyether chain as X may be, for example, a polyoxyalkylene chain. The polyether chain as X may be, for example, a group represented by —X¹—O—X²—O—X³—. X¹ to X³ may each independently be an alkylene group or an alkylene group having one to two carbon atoms (for example, a methylene group or an ethylene group). Examples of the polyether chain as X include —CH₂CH₂—O—CH₂—O—CH₂CH₂—.

Examples of commercially available products of the compound A include Thiokol LP series (dithiol having a disulfide bond, manufactured by Toray Fine Chemicals Co., Ltd.). The compound A can also be obtained by converting a reactive functional group of a compound having a reactive functional group (for example, a carboxy group or a hydroxy group) and a disulfide bond at the terminal into a thiol group. Examples of the compound having a reactive functional group and a disulfide bond at the terminal include 3,3′-dithiodipropionic acid (manufactured by Tokyo Chemical Industry Co., Ltd.), dithiodiethanol, and cystamine.

The content of the compound A may be 15 mass % or more, 25 mass % or more, or 35 mass % or more and may be 80 mass % or less, 70 mass % or less, or 60 mass % or less, based on the total amount of the curable composition (solid content excluding the solvent).

### (Compound B)

The compound B is a compound having two or more functional groups capable of reacting with a thiol group. Examples of the functional group capable of reacting with a thiol group include a cyclic ether group (an oxirane group (an oxiranyl group, an epoxy group), an oxetane group (an oxetanyl group), a tetrahydrofuryl group, a tetrahydropyranyl group, and the like); an isocyanate group; an ethylenically unsaturated group (C═C). The upper limit of the number of functional groups in the compound B may be, for example, ten or less, eight or less, six or less, or four or less.

The compound B may be a compound B1 having a polyether chain and having two or more cyclic ether groups. When the curable composition contains the compound B1 as the compound B, the low molecular weight component generated by irradiating the light meltable resin with light has many polyether chains or many hydroxyl groups and tends to exhibit water solubility, so that the low molecular weight component can be removed with an aqueous solvent.

The cyclic ether group may be an oxirane group from the viewpoint of reactivity and availability. That is, the compound B1 is an oxirane compound (epoxy compound) having a polyether chain and having two or more oxirane groups (an oxiranyl group, an epoxy group). Note that in the present specification, the cyclic ether group includes a group having a cyclic ether structure (a structure containing a cyclic ether group). For example, the oxirane group includes a group having an oxirane structure such as a glycidyl group, a glycidyl ether group, or an epoxy cyclohexyl group (a structure containing an oxirane group (an oxiranyl group, an epoxy group)).

The molecular weight or number average molecular weight of the compound B1 may be, for example, 100 to 1,000,000, 100 to 500,000, 100 to 10,000, 150 to 5,000, or 200 to 2,000. Note that the number average molecular weight is a value in terms of polystyrene using a calibration curve by standard polystyrene by gel permeation chromatography (GPC).

When the cyclic ether group of the compound B1 is an oxirane group (an oxiranyl group, an epoxy group), the epoxy equivalent of the component (B) may be 50 to 2,000 g/eq, 80 to 1,500 g/eq, or 100 to 1,000 g/eq.

The compound B1 may be a compound B1a having two cyclic ether groups or a compound B1b having three or more cyclic ether groups. The compound B1a may be a compound having a linear molecular chain and a terminal group and having a polyether chain in the molecular chain (for example, polymers or oligomers). In this case, the terminal group in the compound B1a may be a cyclic ether group. The compound B1a can be regarded as a compound containing two cyclic ether groups and a group containing a polyether chain and linking the two cyclic ether groups (second linking group). The compound Bib may be a compound having one or more cyclic ether groups as a side chain or a substituent of the second linking group in the compound B1a. The compound B1 may contain both the compound B1a and the compound B1b because the compound can further shorten the curing time and can further improve the light meltability and water solubility.

The compound B1a may be a compound having a linear molecular chain and a terminal group and having a polyether chain in the molecular chain (for example, polymers or oligomers). In this case, the terminal group in the compound B1a may be a cyclic ether group. When the compound B is the compound B1a, a low molecular weight component generated by irradiating the light meltable resin with light tends to be easily removed with an aqueous solvent. The polyether chain as a molecular chain may have a substituent such as a hydroxyl group or an alkyl group which may have a hydroxyl group. The molecular chain in the compound B1a may contain a polyether chain or may consist of a polyether chain.

The compound B1a may be, for example, a compound represented by Formula (2): Z—(Y)ₙ₂—Z (the compound (2)). In the formula, Y represents a polyether chain, and Z represents a cyclic ether group. A plurality of Zs may be the same as or different from each other. n2 represents an integer of 1 or more. n2 may be, for example, 1 or more or 2 or more or may be 1,000 or less. When the compound B1a is the compound (2), the group represented by —(Y)ₙ₂— is the second linking group.

The polyether chain as Y may be, for example, a polyoxyalkylene chain. The polyether chain as Y may be, for example, a group represented by —Y¹—O—Y²—O—Y³—. Y¹ to Y³ may each independently be an alkylene group or an alkylene group having one to three carbon atoms (for example, a methylene group, an ethylene group, or a propylene group). Examples of the polyether chain as Y include —CH₂CH₂—O—CH₂—CH₂—O—CH₂CH₂—.

Examples of commercially available products of the compound B1a include Denacol EX series (EX-850, EX-851, EX-821, EX-830, EX-832, EX-841, EX-861, EX-920, manufactured by Nagase ChemteX Corporation).

The compound B1b may be a compound having one or more cyclic ether groups as a side chain of the second linking group (a polyether chain as Y) in the compound B1a.

Examples of commercially available products of the compound B1b include Denacol EX series (EX-614B, EX-313, EX-512, EX-521, manufactured by Nagase ChemteX Corporation).

The mass ratio of the content of the compound B1 b to the total amount of the contents of the compound B1a and the compound B1b (a content (mass) of the compound B1b/a total amount (mass) of the contents of the compound B1a and the compound B1 b) may be 0.01 to 0.40. When the mass ratio is 0.01 or more, the curing time of the curable composition tends to be further shortened, and when the mass ratio is 0.40 or less, the light meltability and the water solubility tend to be further improved. The mass ratio may be 0.02 or more or 0.03 or more and may be 0.35 or less, 0.30 or less, 0.25 or less, 0.20 or less, 0.15 or less, or 0.10 or less.

The content of the compound B may be 10 mass % or more, 20 mass % or more, or 30 mass % or more and may be 60 mass % or less, 50 mass % or less, or 40 mass % or less, based on the total amount of the curable composition (solid content excluding the solvent).

The ratio of the total number of moles of thiol groups in the compound A to the total number of moles of functional groups in the compound B may be, for example, 0.90 or more or 0.95 or more and may be 1.10 or less or 1.05 or less.

### (Photoradical Generator)

The photoradical generator is a component that generates radicals by light irradiation. As the photoradical generator, for example, a component used as a photopolymerization initiator can be used. Examples of the photoradical generator include an intramolecular cleavage type photoradical polymerization initiator in which the photoradical generator itself is photocleaved by light irradiation to generate two radicals.

Examples of the intramolecular cleavage type photoradical generator include a benzyl ketal-based photoradical generator, an α-aminoalkylphenone-based photoradical generator, an α-hydroxyalkylphenone-based photoradical generator, an α-hydroxyacetophenone-based photoradical generator, and an acylphosphine oxide-based photoradical generator.

Examples of the benzyl ketal-based photoradical generator include 2,2-dimethoxy-1,2-diphenylethane-1-one (Omnirad 651).

Examples of the α-aminoalkylphenone-based photoradical generator include 2-benzyl-2-dimethylamino-1-(4-morpholinophenyl)-butanone-1 (Omnirad 369), 2-methyl-1-[4-(methylthio)phenyl]-2 morpholinopropane-1-one (Omnirad 907), and 2-dimethylamino-2-(4-methyl-benzyl)-1-(4-morpholine-4-yl-phenyl)-butane-1-one (Omnirad 379EG).

Examples of the α-hydroxyalkylphenone-based photoradical generator include 1-hydroxy-cyclohexyl-phenyl-ketone (Omnirad 184).

Examples of the α-hydroxyacetophenone-based photoradical generator include 2-hydroxy-1-{4-[4-(2-hydroxy-2 methyl-propionyl)-benzyl]-phenyl}-2 methyl-propane-1-one (Omnirad 127), and 2-hydroxy-2-methyl-1-phenyl-propane-1-one (Omnirad 1173).

Examples of the acylphosphine oxide-based photoradical generator include 2,4,6-trimethylbenzoyl-diphenyl-phosphine oxide (Omnirad TPO H), and bis(2,4,6-trimethylbenzoyl)-phenylphosphine oxide (Omnirad 819).

The content of the photoradical generator may be 1 mass % or more, 3 mass % or more, or 5 mass % or more and may be 30 mass % or less, 20 mass % or less, or 15 mass % or less, based on the total amount of the curable composition (solid content excluding the solvent).

The ratio of the number of moles of the photoradical generator to the number of moles of the compound A (the number of moles of the photoradical generator/the number of moles of the compound A) may be 0.1 or more, 0.2 or more, or 0.3 or more because the light softening properties are further improved.

### (Curing Accelerator)

The curing accelerator is a component for accelerating the reaction of the compound A and the compound B and includes a component functioning as a catalyst of the curing reaction (catalytic curing agent). Examples of the curing accelerator include an amine compound, an imidazole derivative, quaternary ammonium salt, organometallic salt, and a phosphorus compound.

Examples of the amine compound include dicyandiamide, trimethylamine, triethylamine, tripropylamine, tributylamine, tri-n-octylamine, dimethylethylamine, dimethylpropylamine, dimethylbutylmian, dimethyl-n-octylamine, 1,4-diazabicyclo[2.2.2]octane, 1,8-diazabicyclo[5.4.0]undec-7-ene, benzyldimethylamine, 4-methyl-N,N-dimethylbenzylamine, 2,4,6-tris(dimethylaminomethyl)phenol, and 4-dimethylaminopyridine.

Examples of the imidazole derivative include 1-(1-cyanomethyl)-2-ethyl-4-methyl-1H-imidazole, 2-ethyl-4-methylimidazole, 2-methylimidazole, 2-phenylimidazole, 1-cyanoethyl-2-phenylimidazole, 2-phenyl-4,5-dihydroxymethylimidazole, 2-phenyl-4 methyl-5-hydroxymethylimidazole, 2,4,5-triphenylimidazole, 1-benzyl-2 imidazole, 1,2-dimethylimidazole, and 1-benzyl-2-phenylimidazole.

Examples of the quaternary ammonium salt include tetramethylammonium chloride, tetraethylammonium chloride, tetrabutylammonium chloride, benzyltrimethylammonium chloride, benzyltriethylammonium chloride, benzyltributylammonium chloride, tetramethylammonium bromide, tetraethylammonium bromide, tetrabutylammonium bromide, benzyltrimethylammonium bromide, benzyltriethylammonium bromide, tetramethylammonium iodide, tetraethylammonium iodide, tetrabutylammonium iodide, and benzyltributylammonium iodide.

Examples of the organometallic salt include organometallic salts such as bis(2,4-pentanedionato) zinc (II), zinc octylate, zinc naphthenate, cobalt naphthenate, copper naphthenate, iron acetylacetone, nickel octylate, and manganese octylate.

Examples of the phosphorus compound include tetraphenylphosphonium tetra-p-tolylborate, tetraphenylphosphonium tetraphenylborate, triphenylphosphine, tri-p-tolylphosphine, tris(4-chlorophenyl)phosphine, tris(4-methoxyphenyl) phosphine, tris(2,6-dimethoxyphenyl)phosphine, triphenylphosphine triphenylborane, tetraphenylphosphoniun dicyanamide, and tetraphenylphosphonium tetra(4-methylphenyl) borate.

The content of the curing accelerator may be 0.01 mass % or more, 0.1 mass % or more, or 0.5 mass % or more and may be 10 mass % or less, 5 mass % or less, or 2 mass % or less, based on the total amount of the curable composition (solid content excluding the solvent).

The curable composition may further include components (other components) that do not correspond to the compound A, the compound B, the photoradical generator, and the curing accelerator. Examples of other components include a plasticizer; a tackiness imparting agent such as tackifier; an antioxidant; a leuco dye; a sensitizer; an adhesion improver such as a coupling agent; a polymerization inhibitor; a light stabilizer; an antifoaming agent; a filler; a chain transfer agent; a thixotropy imparting agent; a flame retardant; a mold release agent; a surfactant; a lubricant; and an additive such as an antistatic agent. As these additives, known additives can be used. When the curable composition includes other components, the total content of the other components may be 0 to 95 mass %, 0.01 to 50 mass %, or 0.1 to 10 mass % based on the total amount of the curable composition.

The curable composition may be used as a varnish of the curable composition diluted with a solvent. Examples of the solvent include aromatic hydrocarbon such as toluene, xylene, mesitylene, cumene, and p-cymene; aliphatic hydrocarbon such as hexane and heptane; cyclic alkane such as methylcyclohexane; cyclic ether such as tetrahydrofuran and 1,4-dioxane; ketone such as acetone, methyl ethyl ketone, methyl isobutyl ketone, cyclohexanone, and 4-hydroxy-4-methyl-2-pentanone; ester such as methyl acetate, ethyl acetate, butyl acetate, methyl lactate, ethyl lactate, and γ-butyrolactone; carbonic acid ester such as ethylene carbonate and propylene carbonate; and amide such as N,N-dimethylformamide, N,N-dimethylacetamide, and N-methyl-2-pyrrolidone (NMP). The content of the solid content in the varnish, that is, the content of components other than the solvent in the varnish may be 10 to 95 mass %, 15 to 70 mass %, or 20 to 50 mass % based on the total amount of the varnish.

A step (A) includes, for example, preparing a laminated body 10 including a dicing tape 2 (dicing film) and the semiconductor wafer 1 provided on the dicing tape 2 (see FIG. 1(a)), and disposing a positive photoresist material on the surface of the semiconductor wafer 1 to form the positive photosensitive resin film 4 (see FIG. 1(b)).

When the positive photosensitive resin film 4 includes a light meltable resin, the step (A) includes, for example, preparing the laminated body 10 (see FIG. 1(a)), disposing a curable composition on the surface of the semiconductor wafer 1, and curing the curable composition to form the positive photosensitive resin film 4 including a cured product of the curable composition (see FIG. 1(b)).

Examples of the semiconductor wafer 1 include single crystal silicon, polycrystalline silicon, various ceramics, and compound semiconductors such as gallium arsenide. The semiconductor wafer 1 may have, for example, an electrode such as a through electrode.

The thickness of the semiconductor wafer 1 may be, for example, 10 to 1,000 μm, 20 to 900 μm, or 30 to 800 μm.

Examples of the dicing tape 2 (dicing film) include plastic films such as a polytetrafluoroethylene film, a polyethylene terephthalate film, a polyethylene film, a polypropylene film, a polymethylpentene film, and a polyimide film. Also, the dicing tape may be subjected to a surface treatment such as primer application, a UV treatment, a corona discharge treatment, a polishing treatment, or an etching treatment as necessary. The dicing tape may have tackiness. Such a dicing tape may be a dicing tape obtained by imparting tackiness to the plastic film or a dicing tape obtained by providing a pressure sensitive adhesives layer on one surface of the plastic film. The pressure sensitive adhesive layer may consist of an ultraviolet curable pressure sensitive adhesive or a non-ultraviolet curable pressure sensitive adhesive. The ultraviolet curable pressure sensitive adhesive or the non-ultraviolet curable pressure sensitive adhesive is not particularly limited as long as the pressure sensitive adhesives have a sufficient adhesive force that the semiconductor chip does not scatter in the dicing step, and known pressure sensitive adhesives in the related art can be used.

The thickness of the dicing tape 2 may be, for example, 10 to 1,000 μm, 30 to 500 μm, or 50 to 300 μm.

The laminated body 10 can be obtained by bonding the semiconductor wafer 1 to a surface of the dicing tape 2 to which tackiness is imparted or the surface thereof on which a pressure sensitive adhesive layer is provided.

The laminated body 10 may further include a dicing ring 3 disposed on the dicing tape 2 so as to surround the semiconductor wafer 1. The dicing ring 3 is a ring-shaped jig for fixing the semiconductor wafer 1 in the dicing step.

The curable composition can be prepared, for example, by a method including mixing or kneading the respective components described above. Mixing and kneading can be performed by appropriately combining a disperser such as a normal stirrer, a mixer, a three-roll mill, a ball mill, or a bead mill.

The method for disposing the curable composition on the surface of the semiconductor wafer is not particularly limited. However, examples thereof include a method in which the curable composition is applied onto the surface of the semiconductor wafer 1 using a spin coater, a bar coater, or the like, and a method in which the curable composition is molded into a film, and the molded curable composition film is bonded (transferred) to the semiconductor wafer 1. The curable composition film may be in a semi-cured state (B-stage state) before bonding the curable composition film and the semiconductor wafer 1. The curable composition may be disposed, for example, on the circuit formation surface of the semiconductor wafer 1.

The cured product of the curable composition can be obtained, for example, by heating the curable composition. The reaction of the compound A and the compound B proceeds by heating the curable composition. At this time, the curing accelerator can accelerate the reaction. The reaction product (light meltable resin) of the compound A and the compound B may be, for example, a compound (polymer) having a structure represented by the following formula. Meanwhile, the photoradical generator is less involved in the reaction, and the cured product of the curable composition may include a reaction product (light meltable resin) of the compound A and the compound B and the photoradical generator.

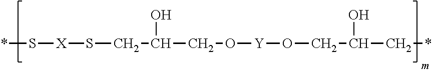

In the formula, X represents a first linking group, and Y represents a second linking group. m represents an integer of 1 or more. m may be, for example, 50 or more, 100 or more, 500 or more, or 1,000 or more. * represents a bond.

The heating temperature of the curable composition may be, for example, 0° C. to 200° C., 30° C. to 150° C., or 60° C. to 100° C. The heating time of the curable composition may be, for example, 0.1 to 168 hours and may be 72 hours or less, 48 hours or less, or 24 hours or less.

The positive photosensitive resin film 4 may be in a (completely) cured state (C-stage state). The thickness of the positive photosensitive resin film 4 may be, for example, 10 to 1,000 μm, 30 to 500 μm, or 50 to 200 μm.

In this manner, the positive photosensitive resin film 4 including the light meltable resin can be formed on the surface of the semiconductor wafer 1.

### <Step (B)>

In this step, a part of the positive photosensitive resin film 4 is exposed, and an exposed portion 4a is provided on the positive photosensitive resin film 4.

The exposure is performed on the positive photosensitive resin film 4, for example, along the line to cut of the semiconductor wafer 1. As a result, the exposed portion 4a subjected to the exposure and an unexposed portion 4b not subjected to exposure can be provided on the positive photosensitive resin film 4 (see FIG. 1(c)).

An irradiation device and irradiation light for performing exposure are not particularly limited as long as the exposed portion 4a and the unexposed portion 4b can be provided. The exposure can be performed, for example, by irradiating laser light A using a laser irradiation device 5. By using the laser irradiation device 5, a desired portion of the positive photosensitive resin film 4 can be selectively irradiated with the laser light A along the line to cut of the semiconductor wafer 1, and the exposed portion 4a and the unexposed portion 4b can be provided.

The laser light A with which the positive photosensitive resin film 4 is irradiated may be, for example, ultraviolet light or visible light. In a case where the positive photosensitive resin film 4 includes a light meltable resin, the wavelength of the laser light A can be arbitrarily set according to, for example, the type of the photoradical generator to be used. The wavelength of the laser light A may be, for example, 150 to 550 nm.

As the laser irradiation device 5, for example, a laser marking device, a laser scribing device, a spotlight irradiation device, or the like can be used.

Examples of another exposure method include a method of performing exposure using an exposure device via a photomask or a reticle as performed by a normal photolithography method. As the exposure device, a contact aligner, a mirror projection, a stepper exposure device, or the like can be used. Examples of the light source include a low-pressure mercury lamp, a high-pressure mercury lamp, an ultra-high-pressure mercury lamp, and a halogen lamp.

### <Step (C)>

In this step, a pattern 6 is formed by developing the positive photosensitive resin film 4 using a developer and removing the exposed portion 4a.

The developer used for development may be an aqueous solvent including an alkaline compound such as sodium hydroxide, potassium hydroxide, sodium hydrogen carbonate, sodium carbonate, sodium silicate, tetramethylammonium hydroxide, or organic amine.

Examples of the aqueous solvent include water and a mixed solvent of water and a hydrophilic organic solvent. In the mixed solvent of water and the hydrophilic organic solvent, the ratio of water can be, for example, 80 mass % or more. For example, additives such as a pH adjusting agent, a detergent, and a surfactant may be added to the aqueous solvent.

The aqueous solvent may be water. Examples of the water include tap water, natural water, purified water, distilled water, ion-exchanged water, pure water, and ultrapure water (Milli-Q water or the like). The Milli-Q water means ultrapure water obtained by a Milli-Q water manufacturing device of Merck Millipore (Merck). Since impurities are reduced, the water may be purified water, distilled water, ion-exchanged water, pure water, or ultrapure water.

Examples of the hydrophilic organic solvent include alcohols such as methanol, ethanol, 2-propanol, and 1,2-propanediol; and glycol ether such as ethylene glycol monomethyl ether, propylene glycol monomethyl ether, ethyl cellosolve, propylene glycol monopropyl ether, propylene glycol monoisopropyl ether, butyl cellosolve, ethylene glycol monoisobutyl ether, propylene glycol monobutyl ether, diethylene glycol dimethyl ether, diethylene glycol diethyl ether, and dipropylene glycol monomethyl ether.

Examples of the pH adjusting agent include inorganic acid, inorganic base, organic acid, and organic base. Examples of the inorganic acid include nitric acid, sulfuric acid, hydrochloric acid, phosphoric acid, and boric acid. Examples of the inorganic base include sodium hydroxide, potassium hydroxide, and calcium hydroxide. Examples of the organic acid include formic acid, acetic acid, propionic acid, butyric acid, acrylic acid, benzoic acid, and picolinic acid. Examples of the organic base include primary amine, secondary amine, tertiary amine, tetramethylammonium hydroxide, tetraethylammonium hydroxide, and an imidazole-based compound.

When the positive photosensitive resin film 4 includes a light meltable resin, the developer to be used for development may be an aqueous solvent having pH of 11 or less. The pH means a hydrogen ion index. The low molecular weight component generated by irradiating the light meltable resin with light has many polyether chains or many hydroxyl groups and tends to exhibit water solubility. Therefore, the low molecular weight component can be removed with a weakly alkaline aqueous solvent or an aqueous solvent including no alkaline compound. In addition, by using an aqueous solvent having pH of 11 or less as the developer, it is possible to suppress defects such as chip scattering due to a decrease in tackiness of the dicing tape 2 to the semiconductor wafer 1, wraparound of the developer to the back surface of the chip, embrittlement of the dicing tape 2, failure in assembly after the next process due to swelling, and corrosion of the dicing ring 3. The pH of the aqueous solvent may be pH of 10 or less, pH of 9 or less, or pH of 8 or less and may be pH of 4 or more, pH of 5 or more, or pH of 6 or more.

By developing the positive photosensitive resin film 4 using a developer (removing the exposed portion 4a using a developer), the unexposed portion 4b remains on the semiconductor wafer 1, and the pattern 6 is formed. In this manner, a laminated body 20 including the dicing tape 2, the semiconductor wafer 1 provided on the dicing tape 2, and the pattern 6 formed on the semiconductor wafer 1 can be obtained (see FIG. 1(d)).

### <Step (D)>

In this step, by performing plasma dicing using the pattern 6 as a mask, the semiconductor wafer 1 is singulated to obtain a patterned semiconductor chip 8.

Plasma used for plasma dicing is generated in a plasma generator 7 under a condition that the semiconductor wafer 1 is etched. The etching conditions can be appropriately selected according to the material of the semiconductor wafer 1. When the material of the semiconductor wafer 1 is silicon, a Bosch process can be used for etching. In the Bosch process, by sequentially repeating a protection film forming step, a protection film etching (anisotropic etching) step, and an Si etching (isotropic etching) step, etching proceeds in the depth direction in a portion S not covered with the pattern 6 (mask) on the surface of the semiconductor wafer 1 (see FIG. 2(a)).

In the protective film forming step, for example, plasma is generated by adjusting the vacuum to medium vacuum (10⁻¹ to 10² Pa) while supplying C₄F₈ or the like as a source gas in the plasma generator 7. Thus, a protective film can be formed on the Si surface or the like.

In the protective film etching step, for example, plasma is generated by adjusting the vacuum to medium vacuum (10⁻¹ to 10² Pa) while supplying SF₆ or the like as a source gas in the plasma generator 7. Thus, the protective film on the Si surface can be etched.

In the Si etching step, for example, plasma is generated by adjusting the vacuum to medium vacuum (10⁻¹ to 10² Pa) while supplying SF₆ or the like as a source gas in the plasma generator 7. Thus, the Si surface can be etched.

In this manner, it is possible to obtain a laminated body 30 including the dicing tape 2 and the plurality of patterned semiconductor chips 8 provided on the dicing tape 2 and having a semiconductor chip 1a and the patterns 6 (see FIG. 2(b)).

### <Step (E)>

In this step, the pattern 6 of the patterned semiconductor chip 8 is exposed.

The exposure is performed on the pattern 6 (see FIG. 2(c)). This makes it possible to increase the solubility of the pattern 6 in a removing liquid described below.

Light B with which the pattern 6 is irradiated may be, for example, ultraviolet light or visible light. In a case where the positive photosensitive resin film 4 includes a light meltable resin, the wavelength of the light B can be appropriately selected according to, for example, the type of the photoradical generator to be used. The wavelength of the light B may be, for example, 150 to 550 nm.

The irradiation with the light B can be performed, for example, using a light irradiation device 9 under the condition that the irradiation amount is 1,000 mJ/cm² or more. The irradiation amount can be appropriately set according to, for example, the wavelength of the light B. The irradiation amount may be, for example, 3,000 mJ/cm² or more, 5,000 mJ/cm² or more, or 10,000 mJ/cm² or more and may be 100,000 mJ/cm² or less, 80,000 mJ/cm² or less, or 60,000 mJ/cm² or less.

The irradiation amount means a product of illuminance and irradiation time (seconds). Examples of the light source for irradiation with ultraviolet light or visible light include a low-pressure mercury lamp, an intermediate-pressure mercury lamp, a high-pressure mercury lamp, a metal halide lamp, and an LED lamp.

### <Step (F)>

In this step, the exposed pattern 6 is removed using the removing liquid to obtain the semiconductor chip 1a in which the pattern 6 is removed from the patterned semiconductor chip 8.

Examples of the removing liquid used for removing the pattern 6 include a liquid the same as the developer. The removing liquid may be an aqueous solvent including an alkaline compound. When the positive photosensitive resin film 4 includes a light meltable resin, the removing liquid may be an aqueous solvent having pH of 11 or less. The pH of the aqueous solvent may be pH of 10 or less, pH of 9 or less, or pH of 8 or less and may be pH of 4 or more, pH of 5 or more, or pH of 6 or more.

In a method for manufacturing a semiconductor device including performing plasma dicing in the related art, a treatment such as high-pressure cleaning and ashing may be performed in removal of a pattern (mask). It can be said that the method for removing the pattern 6 of the present embodiment is a simpler method than the method in the related art because a treatment such as high-pressure cleaning and ashing are not performed. By removing the pattern 6, a laminated body 40 including the dicing tape 2 and the plurality of semiconductor chips 1a provided on the dicing tape 2 can be obtained (see FIG. 2(d)).

The method for manufacturing a semiconductor device of the present embodiment may further include irradiating the pressure sensitive adhesive layer of the dicing tape with ultraviolet light (hereinafter, referred to as “step (G)”), picking up the semiconductor chip (hereinafter, referred to as “step (H)”), bonding the picked-up semiconductor chip and a support member via an adhesive layer (die-bonding film or the like) by thermocompression bonding (hereinafter, referred to as “step (I)”), and a thermally curing step of thermally curing the adhesive layer (hereinafter, referred to as “step (J)”).

### <Step (G)>

When the pressure sensitive adhesive layer of the dicing tape 2 is configured with an ultraviolet curable pressure sensitive adhesive, the method for manufacturing a semiconductor device may include the step (G). In this step, the pressure sensitive adhesive layer is irradiated with ultraviolet light. In the ultraviolet irradiation, the wavelength of the ultraviolet light may be 200 to 400 nm. In the ultraviolet irradiation condition, the illuminance and the irradiation amount may be in a range of 30 to 240 mW/cm² and a range of 50 to 500 mJ/cm², respectively.

### <Step (H)>

In this step, the semiconductor chip 1a pushed up by the needle from the dicing tape 2 side is sucked by the suction collet and picked up from the dicing tape 2 while separating the singulated semiconductor chips 1a from each other.

The ultraviolet irradiation step and the pickup step may be performed after the step (E) and the step (F) or may be performed before the step (E) and the step (F).

### <Step (I)>

In this step, the picked-up semiconductor chip 1a and a support member 11 are bonded to each other by thermocompression bonding via an adhesive layer 12 (die-bonding film or the like). As the die-bonding film, a die-bonding film used in the art can be used. The plurality of semiconductor chips 1a may be bonded to the support member 11.

The heating temperature in the thermocompression bonding may be, for example, 80° C. to 160° C. The load in thermocompression bonding may be, for example, 5 to 15 N. The heating time in the thermocompression bonding may be, for example, 0.5 to 20 seconds.

### <Step (J)>

In this step, the adhesive layer 12 is thermally cured. The heating temperature can be appropriately changed depending on the constituents of the die-bonding film. The heating temperature may be, for example, 60° C. to 200° C., 90° C. to 190° C., or 120° C. to 180° C. The heating time may be 30 minutes to five hours, one to three hours, or two to three hours. The temperature or the pressure may be changed stepwise.

In this manner, a semiconductor device 100 (see FIG. 2(e)) including the semiconductor chip 1a, the support member 11 on which the semiconductor chip 1a is mounted, and the adhesive layer 12 provided between the semiconductor chip 1a and the support member 11 and bonding the semiconductor chip 1a and the support member 11 can be manufactured.

According to the present disclosure, a novel method for manufacturing a semiconductor device including performing plasma dicing is provided. According to the method for manufacturing a semiconductor device of the present disclosure, a pattern (mask) can be formed without performing laser grooving processing, and occurrence of debris itself can be suppressed.

### REFERENCE SIGNS LIST

1: semiconductor wafer, 1a: semiconductor chip, 2: dicing tape 3: dicing ring, 4: positive photosensitive resin film, 4a: exposed portion, 4b: unexposed portion, 5: laser irradiation device, 6: pattern (mask), 7: plasma generator, 8: patterned semiconductor chip, 9: light irradiation device, 10, 20, 30, 40: laminated body, 11: support member, 12: adhesive layer, 100: semiconductor device

1. A method for manufacturing a semiconductor device, the method comprising:
forming a positive photosensitive resin film on a surface of a semiconductor wafer;
exposing a part of the positive photosensitive resin film to light and providing an exposed portion on the positive photosensitive resin film;
developing the positive photosensitive resin film using a developer and removing the exposed portion to form a pattern;
obtaining a patterned semiconductor chip by performing plasma dicing using the pattern as a mask and singulating the semiconductor wafer;
exposing a pattern of the patterned semiconductor chip; and
obtaining a semiconductor chip in which the pattern is removed from the patterned semiconductor chip by removing the pattern exposed by using a removing liquid.

2. The method for manufacturing a semiconductor device according to claim 1,
wherein the positive photosensitive resin film comprises a resin in which the molecular weight is reduced by irradiation with light.

3. The method for manufacturing a semiconductor device according to claim 2,
wherein the developer and the removing liquid are aqueous solvents having pH of 11 or less.

4. The method for manufacturing a semiconductor device according to claim 2, wherein the resin in which the molecular weight is reduced by irradiation with light is a reaction product of a compound A having a disulfide bond and two or more thiol groups and a compound B having two or more functional groups capable of reacting with a thiol group.

5. The method for manufacturing a semiconductor device according to claim 4, the resin layer further comprising a photoradical generator.
